(19) United States
(12) Patent Application Publication
(10) Pub. No.: US 2007/0257662 A1
(43) Pub. Date: Nov. 8, 2007

(54) Current probe

(76) Inventors: Michael J. Mende, Portland, OR (US); Robert A. Nordstrom, Beaverton, OR (US); Thomas J. Sharp, Tigard, OR (US)

Correspondence Address: WILLIAM K. BUCHER;TEKTRONIX, INC., 14150 S.W. KARL BRAUN DRIVE, P.O. BOX 500, MS 50-LAW, BEAVERTON, OR, 97077, US

(21) Appl. No.: 11/430,398

(22) Filed: May 8, 2006

(51) Int. Cl. G01R 15/18

(52) U.S. Cl. 324/117 R

(57) ABSTRACT

A current probe for acquiring a current signal from a current carrying conductor via a current diverting element has a probe body and first and second electrically conductive contacts extending from one end of the probe body for connecting to current diverting element. A current sensing circuit is coupled to the first and second electrically conductive contacts for generating an output signal representative of the current flowing in the current carrying conductor. An electrically conductive cable is coupled to receive the output signal from the current sensing device and extends from the other end of the probe body for coupling to an oscilloscope.

### BACKGROUND OF THE INVENTION

The present invention relates generally to current probes and more particularly to a current probe for use with an oscilloscope for acquiring a current signal from a current carrying conductor.

Current probes used with oscilloscopes apply transformer technology to measure current flowing in a conductor. The transformer has a ring-shaped magnetic core defining an aperture and may be solid or closed core or an open or split core where one side of the magnetic core is movable relative to the other sides. This allows the current carrying conductor to be passed through the aperture of the transformer without having to disconnect the current carrying conductor from a circuit. The current carrying conductor is passed through the aperture in the magnetic core and acts as the primary winding of the transformer. A secondary winding is wrapped around one side of the magnetic core. The current flowing in the current carrying conductor induces a magnetic flux that is linked to the magnetic core and the secondary winding. The magnetic flux causes a current to be generated in the secondary winding that produces a magnetic flux that is opposite to that generated by the current flowing in the current carrying conductor. In a passive current probe, the alternating current generated by the secondary winding is dropped across a transformer termination resistor which generates an AC voltage output. The voltage output is coupled via an electrical cable to an input channel of the oscilloscope. The oscilloscope processes the voltage signal for displaying a representation of the current signal.

Since transformers are AC signal coupling devices, the passband of the transformer cut-off frequency is above the DC level. To allow the current probe to sense DC and low frequency current signals, an active current probe includes a Hall effect device in the magnetic core of the transformer. The Hall effect device is a semi-conductor positioned in the magnetic core such that the magnetic flux in the magnetic core is substantially perpendicular to the Hall plate. A bias is applied to the Hall plate and the resulting voltage generated by the Hall effect due to the flux in the magnetic core is coupled to the input of a differential amplifier. The single ended output of the amplifier may be coupled to a power amplifier which generates a current output proportional to the voltage generated by the Hall effect device. The output of the Hall device amplifier or alternately the power amplifier is coupled to the secondary winding of the transformer such that the output current from the amplifier flowing through the secondary winding produces a flux that opposes the input magnetic flux over the frequency passband of the Hall effect device. In one implementation, the output of the Hall effect or power amplifier is coupled to one side of the secondary winding with the other side of the winding coupled to the transformer termination resistor and amplifier circuitry. In another implementation, the output of the Hall effect amplifier is coupled via a resistor to the same side of the secondary as the amplifier circuitry. A capacitor is coupled to the input of a wideband amplifier in the amplifier circuitry for blocking the current from the Hall effect amplifier. The output of the Hall effect amplifier and the output of the wideband amplifier are summed at the input of a operational amplifier having a feedback resistor that provides a voltage output proportional to the combined current in the secondary winding of the transformer. The voltage output of the operational amplifier is a measure of the AC and DC components of the magnetic core flux. The output of the operational amplifier is coupled via an electrical cable to an input channel of the oscilloscope. Generally, active current probes are of the split-ring transformer type. U.S. Pat. Nos. 3,525,041, 5,477,135 and 5,493,211 describe the above current sensing circuits.

To measure the current passing through a conductor, the current probe must be coupled in series with the conductor. This proves difficult when the current carrying conductor is fixed to a substrate, such as a circuit trace on a circuit board. The general procedure for measuring the current in a current trace is to break the trace and solder a length of wire between the trace break. The wire is passed through the aperture in the transformer of the current probe where the wire acts as the primary winding of the transformer. Another procedure is to manufacture the circuit board with gaps in the traces and install square pins on either side of the gaps. A conductive jumper is coupled to the square pins during normal testing of the circuit board. When a current measurement is required the jumper is removed and a length of wire is connected between the square pins. As before, the wire is used as the primary winding of the transformer in the current probe.

Transformer based current probes have a number of limitations in measuring currents through circuit traces on a circuit board. Besides the requirement of breaking the circuit trace and installing a wire across the break, the sensitivity and accuracy of the resulting current measurement is limited by the repeatability of placing the wire in the same position within the magnetic core of the transformer and the repeatability of the split core being exactly aligned in the same position when it is opened and closed.

What is needed is a current probe that overcomes the above limitations. The current probe should be usable for sensing a current in current carrying conductor without breaking the conductor and installing a wire loop for use as the primary of the current probe transformer. Further, the current probe should provide accurate and repeatable current measurements down to DC.

### SUMMARY OF THE INVENTION

Accordingly, a current probe for use with an oscilloscope for acquiring a current signal from a current carrying conductor via a current diverting device electrically coupled to the current carrying conductor that meets the above described needs has a probe body and first and second electrically conductive contacts disposed in one end of the probe body. The first and second electrically conductive contacts are adapted for coupling in series with the current carrying conductor via the current diverting device. A current sensing circuit is coupled to the first and second electrically conductive contacts for generating an output signal representative of the current flowing in the current carrying conductor. An electrically conductive cable is coupled to receive the output signal from the current sensing device and extends from the other end of the probe body for coupling to the oscilloscope.

The first and second electrically conductive contacts may be electrically conductive pins extending from the end of the probe body for engaging electrically conductive contacts in the current diverting device mounted on the current carrying conductor. Alternately, the first and second electrically conductive contacts form an electrically conductive pin having insulating material disposed in the pin for electrically isolating the first electrically conductive contact from the second electrically conductive contact. The pin extends from the end of the probe body for engaging electrically conductive contacts in the current diverting device. First and second electrically conductive leads may also be coupled to the first and second electrically conductive contacts. Each lead has one end coupled to one of the first and second electrically conductive contacts and the other end coupled to a plug adapted for engaging electrically conductive contacts in the current diverting device. The current diverting device has a first position where the electrically conductive contacts couple the current signal on the current carrying conductor and a second position where the electrically conductive contacts are disengaged and coupled the current signal through the current probe. The current probe may also have a non-conductive protrusion extending from the current probe adjacent to the first and second electrically conductive contacts. The non-conductive protrusion engages at least one of the electrically conductive contacts of the current diverting device for disengaging the electrically conductive contacts of the current diverting device.

The current sensing circuit may be implemented as a magnetic sensor for sensing the magnetic flux of the current signal and coupled to amplifier circuitry for generating the output signal representative of the current flowing in the current carrying conductor. The magnetic sensor may take the form of a transformer or a flux gate. The transformer has a magnetic core with primary and secondary windings wrapped around the magnetic core. The primary winding receives the current signal from the current carry conductor and induces a magnetic flux within the magnetic core and the secondary winding for generating a current signal output in the secondary winding that is coupled to amplifier circuitry. The transformer may further include a magneto-electric converter disposed in the magnetic core that interacts with the magnetic flux within the magnetic core for generating a voltage signal representative of DC to low frequency current signals on the current carrying conductor with the voltage signal being coupled to the amplifier circuitry.

The objects, advantages and novel features of the present invention are apparent from the following detailed description when read in conjunction with appended claims and attached drawings.

### BRIEF DESCRIPTION OF THE DRAWINGS

FIG. 1 is a perspective view of the current probe according to the present invention.

FIG. 2 is a schematic representation of a current sensing circuit in the current probe according to the present invention.

FIG. 3 is a schematic representation of another current sensing circuit in the current probe according to the present invention.

FIG. 4 is a schematic representation of a further current sensing circuit in the current probe according to the present invention.

FIGS. 5A through 5C are cross-sectional view of various current diverting devices adapted for electrically coupling to the current probe according to the present invention.

FIG. 6 is a cross-sectional view of another current diverting device adapted for electrically coupling to the current probe according to the present invention.

FIG. 7 is a further example of the current probe and current diverting device adapted for electrically coupling to the current probe according to the present invention.

### DETAILED DESCRIPTION OF THE INVENTION

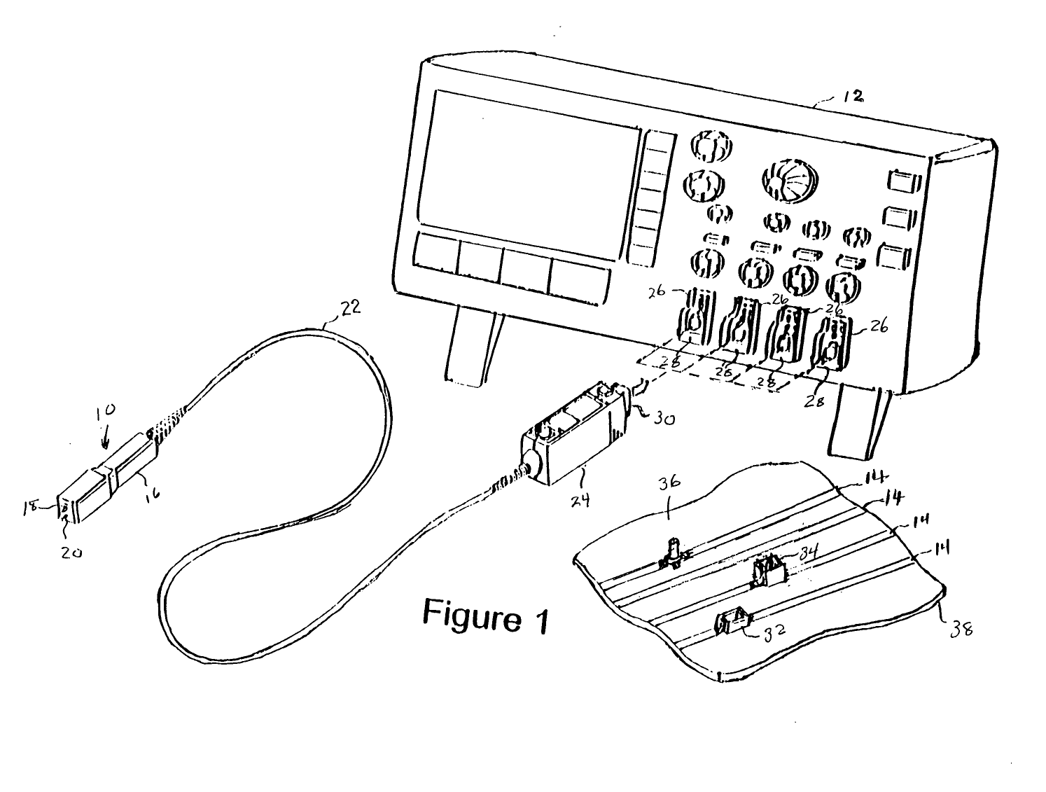

FIG. 1 is a perspective view of current probe 10 for use with an oscilloscope 12 for acquiring a current signal from a current carrying conductor 14. The current probe 10 has a probe body 16 in which is disposed a current sensing circuit. The current sensing circuit is electrically coupled to electrically conductive contacts 18 and 20 disposed in one end of the probe body 16. Extending from the other end of the probe body 16 is a conductive cable 22 for coupling an output signal from the current sensing circuit to the oscilloscope 12 and electrical power to the current sensing circuit. The conductive cable 22 is preferably coupled to a current probe control box 24 that is coupled to one of a number of input signal channel 26 of the oscilloscope 12. Each input signal channels 26 has a receptacle interface 28 with each interface having electrically conductive contacts and a coaxial signal jack. The current probe control box 24 has an plug interface 30 that mates with the receptacle interfaces 28 and has electrical contacts and a coaxial signal jack that interface with the corresponding electrical contacts and coaxial signal jack in receptacle interfaces 28. The interfaces 28 and 30 provide electrical power to the current probe 10 as well as providing communications between the current probe 10 and the oscilloscope 12. The interfaces 28 and 30 also provide a signal path between the current probe 10 and the oscilloscope 12.

The electrically conductive contacts 18 and 20 of the current probe 10 are adapted for electrically coupling to one of a number of current diverting devices 32, 34, 36 mounted on a current carrying conductor 14, such as a circuit trace formed on a circuit board 38 or the like. The current diverting devices 32, 34, 36 are positioned on the current carrying conductor 14 across a non-conductive gap in the current carrying conductor 14. The current diverting devices 32, 34, 36 couple the current signal across the non-conductive gap in a first position and couple the current signal to the current probe 10 in a second position.

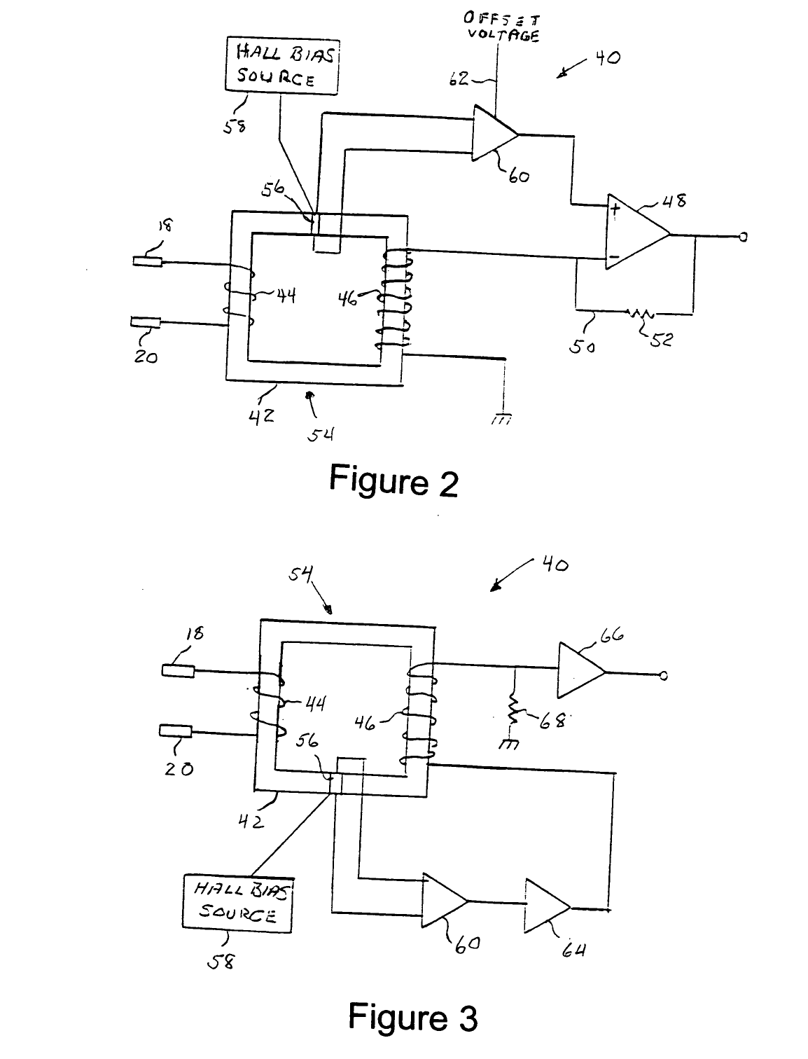

Referring to FIG. 2, there is shown a schematic representation of a current sensing circuit 40 disposed in the probe body 16 of the current probe. The current sensing circuit 40 has a ring-shaped core 42 of magnetic material defining an aperture. The current carrying conductor 14 is coupled via the first and second electrically conductive contacts 18 and 20 to a primary winding 44 that is coupled in series with the current carrying conductor 14. The current carrying conductor 14 is coupled in a flux linking relationship with ring-shaped magnetic core 42 via the primary winding 44. The current to be measured in the current carrying conductor 14 produces a magnetic flux in the magnetic core 42 and is linked to a secondary winding 46. One terminal of the secondary winding 46 is coupled to ground with the other terminal being coupled to the inverting input terminal of a transimpedance amplifier 48. The inverting input terminal of the transimpedance amplifier 48 is coupled to the output terminal of the amplifier 48 via a current signal path 50 having a transimpedance resistor 52. Thus the primary winding 44, the magnetic core 42 and the secondary winding 46 function as a transformer 54. A magneto-electric converter 56 is disposed within the magnetic core 42 substantially perpendicular to the lines of flux in the magnetic core 42. The magneto-electric converter 56 is preferably a thin film semiconductor Hall effect device having a first pair of terminals coupled to a bias source 58 and a second pair of terminals connected to differential inputs of amplifier 60. The amplifier 60 is preferably a high gain differential amplifier having low noise and high common mode rejection The single ended output of the differential amplifier 60 is coupled to the non-inverting input of the transimpedance amplifier 48. Offset control signals resulting from the degaussing of the current sensing circuit 40 may also be applied to the differential amplifier 60 via an offset voltage line 62.

The current in the primary winding 44 produces a magnetic flux in the magnetic core 42 of the transformer 54 that is linked to the secondary winding 46 and the Hall effect device 56. DC or low frequency components of the current flowing the in the primary winding 44 generate a potential difference between the second pair of terminals of the Hall effect device 56. The voltage output of the Hall effect device 56 is coupled to the differential inputs of the amplifier 60. The output of amplifier 60 is coupled to the non-inverting input of the transimpedance amplifier 48. The changing signal level on the non-inverting input of the transimpedance amplifier 48 caused by the voltage generated by the Hall effect device 56 produces a corresponding change in the output voltage level of the transimpedance amplifier 48. The voltage at the output of the transimpedance amplifier 48 results in a current being generated in the current signal path 50 that is coupled to the secondary winding 46 of the transformer 54. The current flowing in the secondary winding 46 is opposite the current flowing in the primary winding 44 producing a magnetic flux in the magnetic core 42 that nulls the magnetic flux produced by the current flowing in the primary winding 44. This DC to low frequency feedback loop maintains an opposing current through the current signal path 50 that is equal to the DC or low current signal in the primary winding 44 of the transformer 54.

The high frequency components of the current flowing in the primary winding 44 results in a current being induced in the secondary winding 46 in a direction such as to produce a magnetic field in the magnetic core 42 that is opposite to the field created by the current in the primary winding 44. The current induced in the secondary winding 46 is coupled to the inverting input of the transimpedance amplifier 48. Since the inverting input is a virtual ground, the current in the secondary winding 46 is coupled via the current signal path 50 through the transimpedance resistor 52 to the output of the transimpedance amplifier 48 resulting in an amplified voltage output representative of the high frequency components of the current flowing in the primary winding 44. The transimpedance amplifier 48 functions as both a power amplifier for generating a bucking current for nulling the magnetic flux in the magnetic core 42 at DC to low current frequencies and as a transimpedance amplifier for higher frequencies. The output of the transimpedance amplifier 48 is coupled to the oscilloscope 12 via the conductive cable 22.

FIG. 3 is a schematic representation of another current sensing circuit 40. Like elements from the previously are labeled the same in FIG. 3. The current sensing circuit 40 has a ring-shaped core 42 of magnetic material defining an aperture. The current carrying conductor 14 is coupled via the first and second electrically conductive contacts 18 and 20 of the current probe 10 to a primary winding 44 that is coupled in series with the current carrying conductor 14. The current carrying conductor 14 is coupled in a flux linking relationship with ring-shaped magnetic core 42 via the primary winding 44. The current to be measured in the current carrying conductor 14 produces a magnetic flux in the magnetic core 42 and is linked to a secondary winding 46. Thus the primary winding 44, the magnetic core 42 and the secondary winding 46 function as a transformer 54. A magneto-electric converter 56 is disposed within the magnetic core 42 substantially perpendicular to the lines of flux in the magnetic core 42. The magneto-electric converter 56 is preferably a thin film semiconductor Hall effect device having a first pair of terminals coupled between a bias source 58 and ground and a second pair of terminals connected to differential inputs of amplifier 60. The amplifier 60 is preferably a high gain differential amplifier having low noise and high common mode rejection The single ended output of the differential amplifier 60 is coupled to a power amplifier 64 whose output is coupled to one end of the secondary winding 46. The other end of the secondary winding 46 is coupled to the input of a voltage gain amplifier 66 via a transformer termination resistor 68 summing node.

The current in the primary winding 44 produces a magnetic flux in the magnetic core 42 of the transformer 54 that is linked to the secondary winding 46 and the Hall effect device 56. DC or low frequency components of the current flowing the in the primary winding 44 generate a potential difference between the second pair of terminals of the Hall effect device 56. The voltage output of the Hall effect device 56 is coupled to the differential amplifier 60 whose output is coupled to the power amplifier 64. The power amplifier 64 generates a current output that is coupled to the secondary winding 46. The current flowing in the secondary winding 46 from the power amplifier 64 is opposite the current flowing in the primary winding 44 producing a magnetic flux in the magnetic core 42 that nulls the magnetic flux produced by the current flowing in the primary winding 44. This opposing current through secondary winding representing the DC or low current signal in the primary winding 44 of the transformer 54 and is coupled to the input of the voltage gain amplifier 66 via the transformer termination resistor 68 summing node.

The high frequency components of the current flowing in the primary winding 44 results in a current being induced in the secondary winding 46 in a direction such as to produce a magnetic field in the magnetic core 42 that is opposite to the field created by the current in the primary winding 44. The current induced in the secondary winding 46 is coupled to the input of voltage gain amplifier 66 via transformer termination resistor 68 summing node. The current flowing in the secondary winding 46 from the power amplifier 64 nulls the magnetic flux in the magnetic core 42 for DC to low frequency current signals. The current induced in the secondary winding 46 by the current flowing in the primary winding 44 nulls the magnetic flux in the magnetic core 42 for high frequency current signals. The transition range between the current flowing in the secondary winding 46 from the power amplifier 64 and the current induced into the secondary winding 46 at higher frequencies results in the currents from both sources being summed at the transformer termination resistor 68 summing node. The output of the voltage gain amplifier 66 is coupled to the oscilloscope 12 via the conductive cable 22.

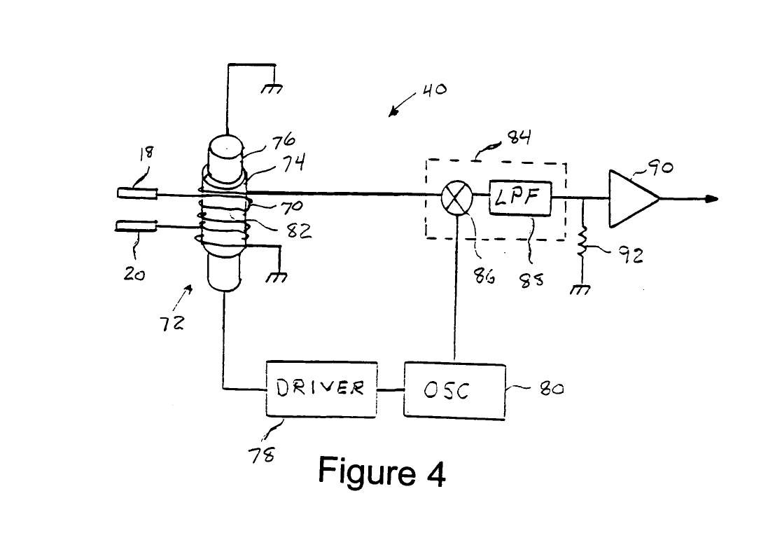

FIG. 4 is a schematic drawing of a further current sensing circuit 40. The current carrying conductor 14 is coupled via the first and second electrically conductive contacts 18 and 20 of the current probe 10 to an input winding 70 of an orthogonal flux gate 72 that is coupled in series with the current carrying conductor 14. The orthogonal flux gate 72 has a cylindrical magnetic core 74 around which the input winding 70 is wrapped. A conductive bar 76 is disposed coaxially through the cylindrical magnetic core 74 and is coupled to a driver circuit 78 coupled to an oscillator 80. A detecting coil 82 is placed around the cylindrical magnetic core 74 for detecting the magnetic flux of the current signal on the input winding and the magnetic flux of a signal from the oscillator 80. The detecting coil 82 is coupled to a detection circuit 84 having a mixer 86 that receives a signal from the oscillator 80 that is twice the frequency of the signal applied to the conductive bar 76. The mixer 86 is coupled to a low pass filter (LPF) 88 which in turn is coupled to an output amplifier 90 via a termination resistor 92.

The driver circuit 78 generates an oscillating drive current that causes the magnetic core 74 to saturate at the peaks of the drive current signal so that the magnetic flux leaves the magnetic core 74 and is aligned with the conductive bar 76. During these periods, the degree of magnetization of the core 74 in the longitudinal direction is decreasing. As the driving current approaches the zero crossing points, the magnetic flux again passes through the magnetic core 74. During these periods, the degree of magnetization of the core 74 in the longitudinal direction is increasing. The direction and density of the magnetic flux in the magnetic core changes according to the changes in the driving current. The voltage output induced into the detecting coil 82 with the current drive signal applied to the flux gate 72 has two cycles for each cycle of the drive current. A current signal applied to the input winding 70 modulates the magnetic flux in the magnetic core producing a modulated voltage output at detecting coil 82 representative of the current signal on the input winding. The modulated output voltage on the detecting coil 82 is coupled to the mixer 86. The mixer 86 multiplies the modulated output voltage with the oscillator signal that is twice the frequency of the drive current. The low pass filter 88 filters the output of the mixer to provide a voltage proportional to the current flowing the input winding 70. The output amplifier 90 receive the filter signal and generates an amplified voltage output. The voltage output of amplifier 90 is coupled to the oscilloscope 12 via the conductive cable 22. The above described current sensing circuits 40 are by example only and modifications to the above circuits may be made without departing from the scope of the invention.

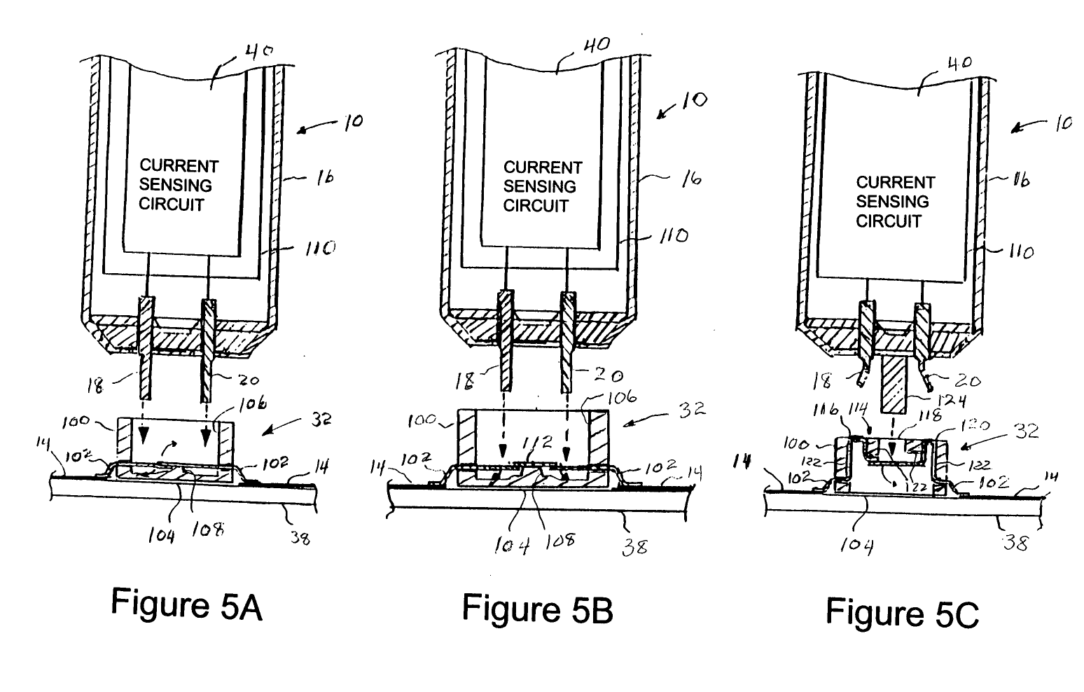

As previously stated, the current probe 10 is adapted for electrically coupling to one of a number of current diverting devices 32, 34, 36 mounted on a current carrying conductor 14, such as a circuit trace formed on a circuit board 38 or the like. Referring to FIGS. 5A through 5C, there are shown cross-sectional views of examples of the current diverting device 32 and a portion of the current probe 10. The current diverting devices 32 in each of the drawing FIGS. 2A through 2C have a housing 100 and electrically conductive contacts 102 extending in opposite direction from the housing 100. The electrically conductive contacts 102 are coupled to the current carrying conductor 14 formed on the circuit board 38 on either side of the non-conductive gap 104. The housing 100 in FIG. 5A has a recess 106 in which is formed a raised pedestal 108 extending up from the bottom of the recess 106. The electrically conductive contacts 102 extend into the recess 106 of the housing 100 with one of the contacts 102 extending across and partially resting on the pedestal 108 and overlapping a portion of the other electrically conductive contact. The overlapped portions of the electrically conductive contacts 102 act as switch elements where electrically conductive contacts 102 couple the current signal across the non-conductive gap 104 in the current carrying conductor 14 in the first current diverting device position.

The probe body 16 of the current probe 10 has a circuit board 110 on which is disposed the current sensing circuit 40. The current sensing circuit 40 is coupled to the first and second electrically conductive contacts 18 and 20 that extend from the probe body 16. The current probe 10 is positioned over and lowered into the current diverting device 32. The downward pressure of the first and second electrically conductive contacts on the electrically conductive contacts 102 of the current diverting device 32 causes the electrically conductive contact 102 partially resting on the pedestal 108 to deflect upward and the other electrically conductive contact 102 to deflect downward. The resulting movement causes the electrically conductive contacts 102 to disengage. The current signal is diverted from the current carrying conductor 14 through the current sensing circuit 40 of the current probe 10 and back to the current carrying conductor 14 via the electrically conductive contacts 102 and the first and second electrically conductive contacts 18 and 20 of the current probe 10. The current diverting device 32 couples the current probe 10 in series with the current carrying conductor 14 and is the second position of the current diverting device 32. Removal of the current probe 10 from the housing recess 106 releases the downward pressure on the electrically conducive contacts 102 which causes the contacts to re-engage each other.

The current diverting device 32 in FIG. 5B is similar to the current diverting device 32 in FIG. 5A in that it has a housing 100 having a recess 106 in which is formed a raised pedestal 108 extending up from the bottom of the recess 106. The electrically conductive contacts 102 extend into the recess 106 of the housing 100. An electrically conductive element 112 is secured to the raised pedestal 108 with opposing ends of the electrically conducive element extending past the pedestal 108 and overlapping the electrically conducive contacts 102. The overlapped portions of the electrically conductive contacts 102 and the electrically conductive element 112 act as switch elements where electrically conductive contacts 102 and the electrically conductive element 112 couple the current signal across the non-conductive gap 104 in the current carrying conductor 14 in the first current diverting device position.

The current probe 10 is positioned over and lowered into the current diverting device 32. The downward pressure of the first and second electrically conductive contacts 18 and 20 on the electrically conductive contacts 102 of the current diverting device 32 causes the electrically conductive contacts 102 to deflect downward. The resulting movement of the electrically conducive contacts 102 causes the contacts 102 to disengage from the electrically conductive element 112. The current signal is diverted from the current carrying conductor 14 through the current sensing circuit 40 of the current probe 10 and back to the current carrying conductor 14 via the electrically conductive contacts 102 and the first and second electrically conductive contacts 18 and 20 of the current probe 10. As with the previously described current diverting device 32, the current probe 10 is coupled in series with the current carrying conductor 14 in the second position of the current diverting device 32. Removal of the current probe 10 from the housing recess 106 releases the downward pressure on the electrically conducive contacts 102 which causes the contacts 102 to re-engage with the electrically conductive element 112.

FIG. 5C illustrates another form of the current diverting device 32. The current diverting device 32 in FIG. 5C has a housing 100 having a top surface 114 in which three apertures 116, 118, 120 are formed. The electrically conductive contacts 102 extend into the housing 100 and are bent upward along the interior sidewalls 122. The electrically conductive elements 102 are bent horizontally at a substantially ninety degree angle to form electrical contact pads exposed in the respective apertures 116 and 120 in the top surface 114 of the housing 100. The electrically conductive contacts 102 are then bent downward at a substantially ninety degree angle along an intermediate interior wall 122 extending into the housing 100 defining the aperture 118. One side of the intermediate interior wall 122 extends farther into the housing 100 than the other side. One of the electrically conductive contacts 102 is bent horizontally at a substantially ninety degree angle along the underside of the longer side of the interior intermediate wall 122 defining a switch element. The other electrically conductive contact 102 is bent horizontally at a substantially ninety degree angle at a distance below the shorter side of the interior intermediate wall 122. The horizontal portion of the electrically conductive contact 102 that is below the shorter side of the interior intermediate wall 122 extends across the aperture 118 and overlaps the electrically conductive contact 102 along the underside of the longer side of the interior intermediate wall 122 defining a mating switch element. The overlapped portions of the electrically conductive contacts 102 couple the current signal across the non-conductive gap in the current carrying conductor 14 in the first current diverting device position.

The probe body 10 of the current probe 10 has a non-conductive protrusion 124 extending from the probe body 16 adjacent to the first and second electrically conductive contacts 18 and 20. The electrically conductive contacts 18 and 20 are angled slightly outward to mate with the electrically conductive contacts 102 in apertures 116 and 120 and allow flexing of the contacts 18 and 20 with downward movement of the current probe 10. The current probe 10 is positioned over and lowered into the current diverting device 32 with the non-conductive protrusion 124 aligned with the aperture 118. The downward movement of the current probe 10 causes the non-conductive protrusion 124 to contact the electrically conductive contact 102 extending across the aperture 118 and at the same time causing the electrically conductive contacts 18 and 20 to contact the electrically conductive contacts 102 in the aperture 116 and 120. Continued downward pressure on the current probe 10 causes the non-conductive protrusion 124 to deflect the electrically conductive contact 102 extending across the aperture 118 and disengage the electrically conductive contacts 102. The current signal is diverted from the current carrying conductor 14 through the current sensing circuit 40 in the current probe 10 and back to the current carrying conductor 14 via the electrically conductive contacts 102 and the first and second electrically conductive contacts 18 and 20 of the current probe 10. Removal of the current probe 10 from the housing 100 releases the downward pressure of the non-conductive protrusion 124 on the electrically conducive contact 102 extending across the aperture 118 which causes the contacts 102 to re-engage each other.

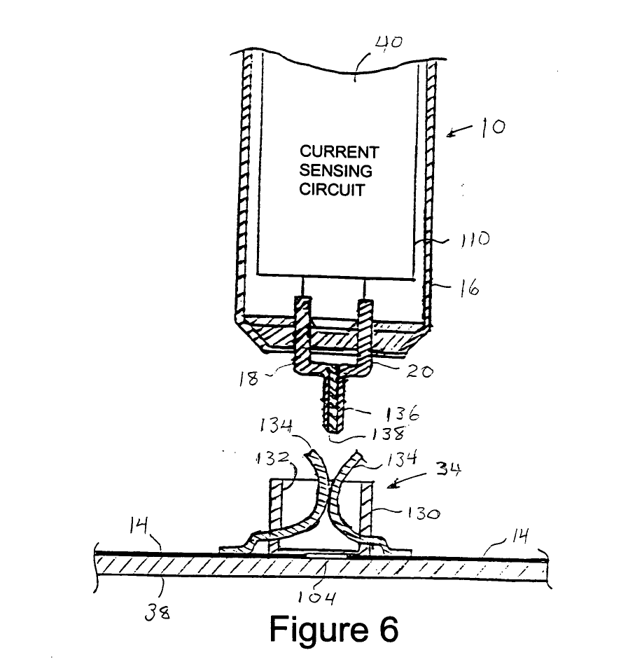

FIG. 6 is a perspective close-up view of the current diverting device 34. The current diverting device 34 has a housing 130 defining a recess 132 therein in which are disposed convex shaped electrically conductive contacts 134. The apex of the convex shaped contacts 134 are in mating electrical contact. The upper diverging portions of the convex contacts 134 form a V-shaped region for receiving the first and second electrically conductive contacts of the current probe 10. The lower diverging portions of the convex contacts 134 extend through the housing 130 and contact the current carrying conductor 14 on either side of the non-conductive gap 104. The mating portion of the convex electrically conductive contacts 134 act as switch elements where electrically conductive contacts 134 couple the current signal across the non-conductive gap 104 in the current carrying conductor 14 in the first current diverting device position.

For use with the type of current diverting device 34, the electrically conductive contacts 18 and 20 of the current probe 10 are modified to form a pin 136 having an insulating material 138 disposed between the first and second electrically conductive contacts 18 and 20 for electrically isolating contacts 18 and 20 from each other. The first and second electrically conductive contacts 18 and 20 extend from the probe body 16 and are angled toward each other and then downward to form the pin 136. The current probe 10 is positioned over and lowered into the current diverting device 34 so that the pin 136 is positioned in the V-shaped region of the convex shaped electrically conductive contacts 134. The downward movement of the pin 136 into the V-shaped region of the convex contacts 134 electrically couples the first and second electrically conductive contacts 18 and 20 of the pin 136 to the convex shaped electrically conductive contacts 134 and causes the mating apexes of the electrically conductive contacts 134 to disengage. The current signal is diverted from the current carrying conductor 14 through the current sensing circuit 40 of the current probe 10 and back to the current carrying conductor 14 via the electrically conductive contacts 134 and the first and second electrically conductive contacts 18 and 20 of the current probe 10. The current diverting device 34 couples the current probe 10 in series with the current carrying conductor 14 and is the second position of the current diverting device 34. Removal of the pin 136 from between the convex shaped electrically conductive contacts 134 causes the apexes of the convex shaped contacts 134 to re-engage.

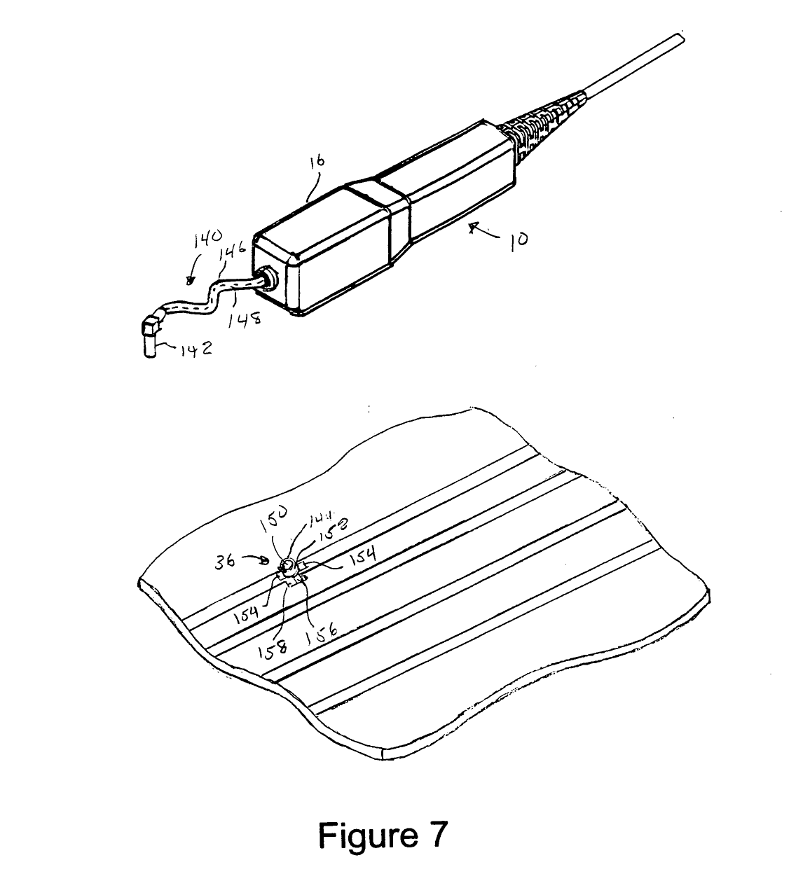

FIG. 7 is a perspective view of a further example of the current probe 10. Extending from the probe body 16 of the current probe 10 is a cable 140 having a coaxial connector 142 for mating with a coaxial receptacle 144 of the current diverting device 36. The first and second electrically conductive contacts 18 and 20 are first and second electrically conductive leads 146 and 148 disposed in the cable 140. One of the leads 146, 148 is electrically coupled to a center electrical conductor in the coaxial connector 142 and the other lead electrically is coupled to the electrically conductive outer body of the connector 142. The center electrical conductor and the electrically conductive outer body of the coaxial connector 142 are insulated from each other. The coaxial receptacle 144 of the current diverting device 36 has a central bore 150 insulated from an outer electrically conductive sleeve 152. Extend in opposite direction from the coaxial receptacle are electrically conductive contacts 154 that are fixedly secured to the current carrying conductor 14 on either side of the non-conductive gap 104 using solder, electrically conductive adhesive or the like. The electrically conductive contacts 154 extend into the coaxial receptacle 144 with one of the electrically conductive contacts extending across the central bore 150 to overlap the other electrically conductive contact 156 to act as switch elements. One of the electrically conductive contacts 154 is electrically coupled to the electrically conductive sleeve 152 via electrically conductive leads 156 extending from the coaxial receptacle 144 in a direction perpendicular to the other electrically conductive leads 154 and electrically coupled to the current carrying conductor 14 on the other side of the non-conductive gap 104 via contact pads 158 formed on the circuit board 38. The electrically conductive contacts 154 couple the current signal across the non-conductive gap 104 in the current carrying conductor 14 in the first current diverting device position.

The coaxial connector 142 is secured to the coaxial receptacle 144 of the current diverting device 36 with the electrically conductive outer body of the coaxial connector 142 electrically coupled to the outer electrically conductive sleeve 150 of the coaxial receptacle 144. The central electrical conductor of the coaxial connector 142 extends into the central bore 150 of the coaxial receptacle 144 and engages the electrically conductive contact 156 extending into the bore 150. The central electrical conductor of the coaxial connector 142 exerts downward pressure on the electrically conductive contact 156 causing the contact 156 to disengage from the other electrically conductive contact 156. The current signal is diverted from the current carrying conductor 14 through the current sensing circuit 40 of the current probe 10 and back to the current carrying conductor 14 via one of the electrically conductive contacts 156 coupled to the central conductor of the coaxial connector 142 and to the current probe 10 via one of the electrically conductive leads 146 and 148 and the other electrically conductive contact 156 coupled to the outer electrically conductive sleeve 152 of the coaxial receptacle 144 and the electrically conductive outer body of the coaxial connector 142 and to the current probe 10 via the other of the electrically conductive leads 146 and 148. The mating of the coaxial connector 142 with the coaxial receptacle 144 of the current diverting device 36 couples the current probe 10 in series with the current carrying conductor 14 and is the second position of the current diverting device 36. Removal of the coaxial connector 142 from the current diverting device 36 releases the downward pressure on the electrically conducive contact 156 which causes the contacts 156 to re-engage each other. The above described current diverting device 36 and mating coaxial connector 142 are manufactured and sold by Amphenol, Corp., Wallingford, Conn., as a RF-Switch and RF-Probe under respective Part Nos. MCH-201 and MCH203.

A current probe has been described having a probe body and first and second electrically conductive contacts extending from one end of the probe body. A current sensing circuit is coupled to the first and second electrically conductive contacts for generating an output signal representative of the current flowing in a current carrying conductor. An electrically conductive cable is coupled to receive the output signal from the current sensing device and extends from the other end of the probe body for coupling to an oscilloscope. The current probe is adapted for electrically coupling to one of a number of current diverting devices mounted on a current carrying conductor formed on a circuit board

It will be obvious to those having skill in the art that many changes may be made to the details of the above-described embodiments of this invention without departing from the underlying principles thereof. The scope of the present invention should, therefore, be determined only by the following claims.

1. A current probe for use with an oscilloscope for acquiring a current signal from a current carrying conductor via a current diverting device electrically coupled to the current carrying conductor wherein the current diverting device couples the current signal through the current carrying conductor in a first position and couples the current signal through the current probe in a second position, the current probe comprising:
a probe body;
first and second electrically conductive contacts disposed in one end of the probe body for coupling in series with the current carrying conductor via the current diverting device;
a current sensing circuit having a magnetic sensor in the form of a transformer having primary and secondary windings and a magnetic core with the primary winding coupled to receive the current signal from the current carry conductor via the first and second electrically conductive contacts and inducing a magnetic flux within the magnetic core and the secondary winding for generating a current signal output in the secondary winding that is coupled to amplifier circuitry for generating an output signal representative of the current flowing in the current carrying conductor; and
an electrically conductive cable coupled to receive the output signal from the current sensing device and extending from the other end of the probe body for coupling to the oscilloscope.

2. The current probe as recited in claim 1 wherein the first and second electrically conductive contacts are electrically conductive pins extending from the end of the probe body for engaging electrically conductive contacts acting as switch elements in the current diverting device wherein downward pressure of the first and second electrically conductive contacts extending from the probe body on the electrically conductive contacts of the current diverting device causes the electrically conductive contacts of the current diverting device to disengage in the second current diverting device position.

3. The current probe as recited in claim 1 wherein the first and second electrically conductive contacts are electrically conductive pins extending from the end of the probe body for engaging electrically conductive contacts acting as switch elements in the current diverting device with a non-conductive protrusion extending from the probe body adjacent to the first and second electrically conductive contacts extending from the end of the probe body for engaging one of the electrically conductive contacts in the current diverting device wherein downward pressure of the non-conductive protrusion extending from the probe body on the electrically conductive contact of the current diverting device causes the electrically conductive contacts of the current diverting device to disengage in the second current diverting device position.

4. The current probe as recited in claim 1 further comprising first and second electrically conductive leads with each lead having one end coupled to one of the first and second electrically conductive contacts and the other end coupled to a plug engaging electrically conductive contacts acting as switch elements in the current diverting device wherein downward pressure of the plug on at least one of the electrically conductive contacts of the current diverting device causes the electrically conductive contacts of the current diverting device to disengage in the second current diverting device position.

5. The current probe as recited in claim 1 wherein the first and second electrically conductive contacts form an electrically conductive pin having insulating material disposed in the electrically conductive pin for electrically isolating the first electrically conductive contact from the second electrically conductive contact, the electrically conductive pin extending from the end of the probe body for engaging electrically conductive contacts in the current diverting device wherein downward pressure of the electrically conductive pin on the electrically conductive contacts of the current diverting device causes the electrically conductive contacts of the current diverting device to disengage in the second current diverting device position.

6. The current probe as recited in claim 1 wherein the current sensing circuit further comprises a magnetic sensor for sensing the magnetic flux of the current signal and coupled to amplifier circuitry for generating the output signal representative of the current flowing in the current carrying conductor.

7. The current probe as recited in claim 6 wherein the magnetic sensor further comprises a transformer having primary and secondary windings and a magnetic core with the primary winding coupled to receive the current signal from the current carry conductor and inducing a magnetic flux within the magnetic core and the secondary winding for generating a current signal output in the secondary winding that is coupled to amplifier circuitry.

8. The current probe as recited in claim 1 wherein the magnetic core of the transformer is ring-shaped and defines an aperture with primary winding disposed around a portion of the ring-shaped magnetic core of the transformer.

9. The current probe as recited in claim 1 wherein the transformer further comprises a magneto-electric converter disposed in the magnetic core of the transformer and interacting with the magnetic flux within the magnetic core for generating a voltage signal representative of DC to low frequency current signals on the current carrying conductor with the voltage signal being coupled to the amplifier circuitry.

10. The current probe as recited in claim 6 wherein the magnetic sensor further comprises a flux gate.
